(19) United States
(12) Patent Application Publication
(10) Pub. No.: US 2014/0030893 A1
(43) Pub. Date: Jan. 30, 2014

(54) METHOD FOR SHRINK AND TUNE TRENCH/VIA CD

(71) Applicants: Ming-Shu KUO, San Ramon, CA (US); Siyi LI, Fremont, CA (US); Monica TITUS, Sunnyvale, CA (US); Srikanth RAGHAVAN, Fremont, CA (US); Tae Won KIM, Dublin, CA (US); Gowri KAMARTHY, Pleasanton, CA (US)

(72) Inventors: Ming-Shu KUO, San Ramon, CA (US); Siyi LI, Fremont, CA (US); Monica TITUS, Sunnyvale, CA (US); Srikanth RAGHAVAN, Fremont, CA (US); Tae Won KIM, Dublin, CA (US); Gowri KAMARTHY, Pleasanton, CA (US)

(73) Assignee: LAM RESEARCH CORPORATION, Fremont, CA (US)

(21) Appl. No.: 13/556,541

(22) Filed: Jul. 24, 2012

(51) Int. Cl. H01L 21/302

(52) U.S. Cl. 438/703; 257/E21.214

(57) ABSTRACT

A method for etching with CD reduction, an etch layer disposed below a silicon containing mask layer under a patterned organic mask with features with a first CD. Features are opened in the silicon containing mask layer using the patterned organic mask, comprising providing an opening gas with an etchant component and polymerizing component, forming the opening gas into a plasma, and providing a pulsed bias with a pulse frequency between 10 Hz and 1 kHz, which etches features through the silicon containing mask layer with a second CD, which is less than half the first CD, forming a pattern in the silicon containing mask layer. The pattern of the silicon containing mask layer is transferred to the etch layer.

### BACKGROUND OF THE INVENTION

### Field of the Invention

The invention relates to a method of forming semiconductor devices on a semiconductor wafer. More specifically, the invention relates to etching features with reduced CD.

In forming semiconductor devices, some devices may be formed by etching an etch layer.

### SUMMARY OF THE INVENTION

To achieve the foregoing and in accordance with the purpose of the present invention, a method for etching with CD reduction an etch layer disposed below a silicon containing mask layer under a patterned organic mask with features with a first CD. Features are opened in the silicon containing mask layer using the patterned organic mask, comprising providing an opening gas with an etchant component and polymerizing component, forming the opening gas into a plasma, and providing a pulsed bias with a pulse frequency between 10 Hz and 1 kHz, which etches features through the silicon containing mask layer with a second CD, which is less than half the first CD, forming a pattern in the silicon containing mask layer. The pattern of the silicon containing mask layer is transferred to the etch layer.

In another manifestation of the invention, a method for etching with CD reduction, an etch layer disposed below an organic underlayer disposed below a silicon containing mask layer under a patterned organic mask with features with a first CD is provided. Features are opened in the silicon containing mask layer using the patterned organic mask, comprising providing an opening gas with an etchant component and polymerizing component, forming the opening gas into a plasma, and providing a pulsed bias with a pulse frequency between 10 Hz and 1 kHz, which etches features through the silicon containing mask layer with a second CD, which is less than half the first CD, forming a pattern in the silicon containing mask layer. The pattern of the silicon containing mask layer is transferred to the organic underlayer. The pattern of the organic underlayer is transferred to the etch layer.

These and other features of the present invention will be described in more details below in the detailed description of the invention and in conjunction with the following figures.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 is a flow chart of an embodiment of the invention.

FIG. 2 is a more detailed flow chart of opening features with reduced CD.

FIG. 3 is a more detailed flow chart of etching features in the etch layer.

FIGS. 4A-D are schematic cross-sectional views of a stack etch according to an embodiment of the invention.

FIG. 5 is a schematic view of a plasma processing chamber that may be used in an embodiment of the invention.

FIG. 6 is a schematic view of a computer system that may be used in practicing the invention.

### DETAILED DESCRIPTION OF THE PREFERRED EMBODIMENTS

The present invention will now be described in detail with reference to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

Due to lithography resolution limits, etch-introduced critical dimension (CD) shrinkage is required for patterning of trench/via beyond 20 nm technology. Conventionally, this is achieved by increasing the ratio of polymerizing fluorocarbon gas in a chemistry or reducing electrostatic chuck (ESC) temperature in etch recipes. As scaling continues, plasma etch processes become more challenging. The high demand for CD shrinkage constrains tunability of gas chemistry or ESC temperature, which is very critical for managing other etch performances in terms of process and productivity requirements.

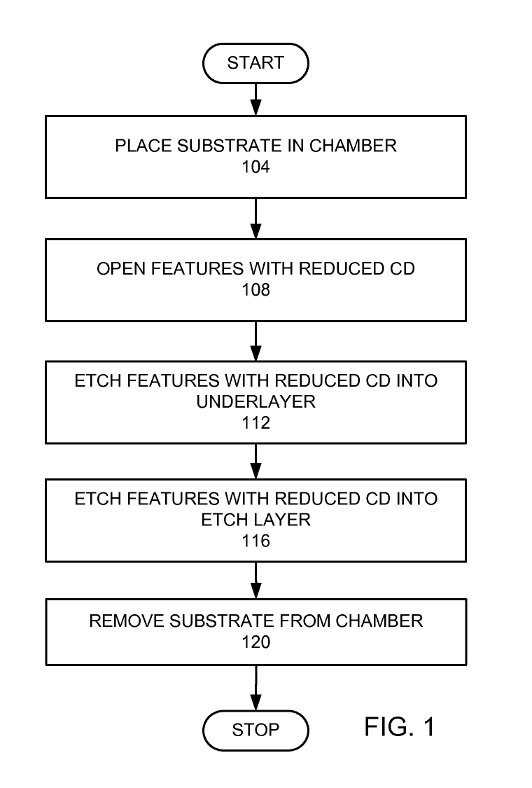

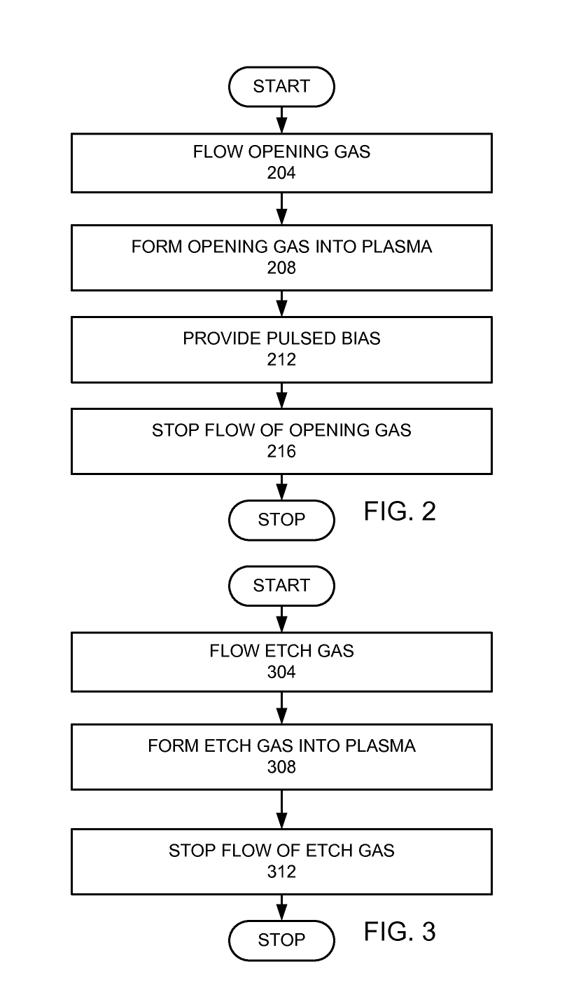

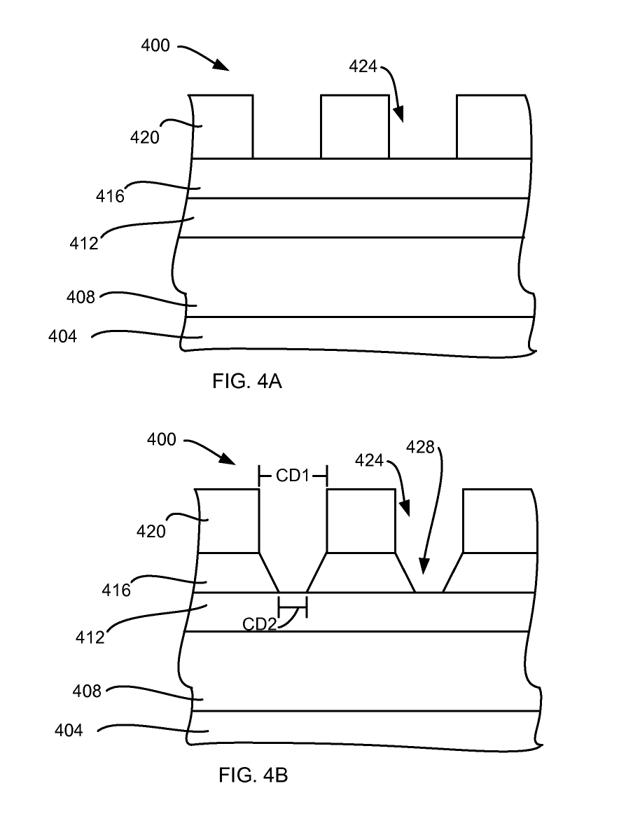

FIG. 1 is a high level flow chart of an embodiment of the invention. In this embodiment, a substrate is placed in an etch chamber (step 104). Preferably, the substrate has an etch layer disposed below an organic underlayer disposed below a silicon containing mask layer disposed below a patterned organic mask. Features are opened in the silicon containing mask layer using the patterned organic mask (step 108), where the opened features in the silicon containing layer have a CD less than half the CD of the features in the organic mask. FIG. 2 is a more detailed flow chart of the step of opening the features with reduced CD (step 108). An opening gas is flowed into the etch chamber (step 204). The opening gas is formed into a plasma (step 208). A pulsed bias is provided (step 212). The flow of the opening gas is stopped (step 216). Using the features with reduced CD in the silicon containing layer as a mask, features with reduced CD are etched into the organic underlayer (step 112). FIG. 3 is a more detailed flow chart of the step of etching features with reduced CD into the organic underlayer (step 112). An etch gas is flowed into the etch chamber (step 304). The etch gas is formed into a plasma (step 308). The flow of the etch gas is stopped (step 312). Using the features with reduced CD in the organic underlayer, features with reduced CD are etched into the etch layer (step 116). Additional process steps may be performed on the substrate while in the etch chamber. The substrate is then removed from the etch chamber (step 120).

### EXAMPLE

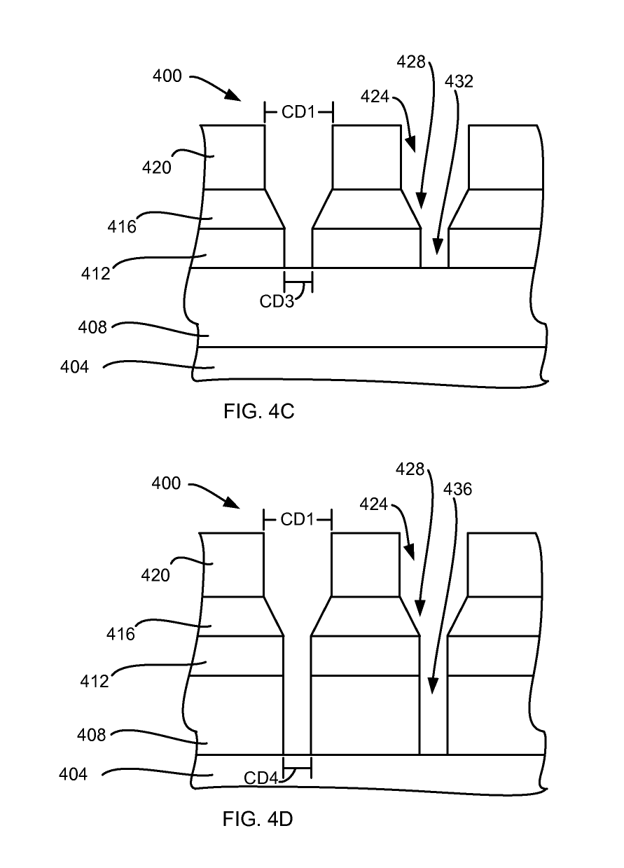

In a preferred embodiment of the invention, a substrate with an etch layer of silicon oxide disposed under organic underlayer disposed under a silicon containing antireflective coating (SiARC) disposed below patterned organic mask of 193 nm photoresist with features with CD greater than 40 nm is placed in an etch chamber (step 104). FIG. 4A is a schematic cross-sectional view of a stack 400 with a substrate 404 with an etch layer 408 disposed below an organic underlayer 412, disposed below a SiARC 416, disposed below a photoresist mask 420 with patterned features 424 with a CD of greater than 40 nm. In this example, one or more layers may be disposed between the substrate 404 and the etch layer 408, or the etch layer 408 and the organic underlayer 412 or the organic underlayer 412 and the SiARC 416.

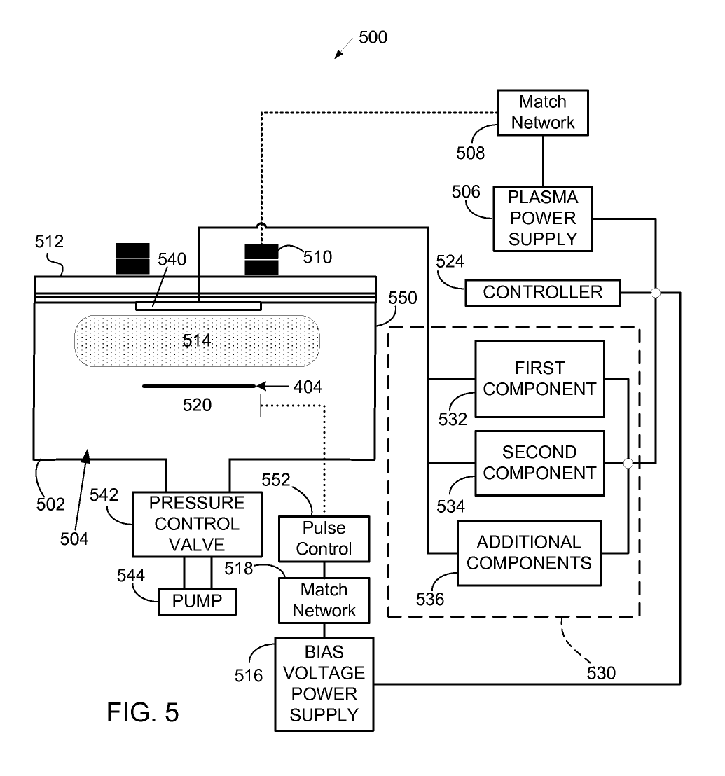

FIG. 5 schematically illustrates an example of a plasma processing system 500 which may be used in one embodiment of the present invention. The plasma processing system 500 includes a plasma reactor 502 having a plasma processing chamber 504 therein defined by a chamber wall 550. A plasma power supply 506, tuned by a match network 508, supplies power to a TCP coil 510 located near a power window 512 that provides power to the plasma processing chamber 504 to create a plasma 514 in the plasma processing chamber 504. The TCP coil (upper power source) 510 may be configured to produce a uniform diffusion profile within processing chamber 504. For example, the TCP coil 510 may be configured to generate a toroidal power distribution in the plasma 514. The power window 512 is provided to separate the TCP coil 510 from the plasma chamber 504 while allowing energy to pass from the TCP coil 510 to the plasma chamber 504. A wafer bias voltage power supply 516 tuned by a match network 518 provides power to an electrode 520 to set the bias voltage on the silicon substrate 404, which is supported by the electrode 520, so that the electrode 520 in this embodiment is also a substrate support. A pulse controller 552 causes the bias voltage to be pulsed. The pulse controller 552 may be between the match network 518 and the substrate support, or between the bias voltage power supply 516 and the match network 518, or between the controller 524 and the bias voltage power supply 516, or in some other configuration to cause the bias voltage to be pulsed. A controller 524 sets points for the plasma power supply 506 and the wafer bias voltage supply 516.

The plasma power supply 506 and the wafer bias voltage power supply 516 may be configured to operate at specific radio frequencies such as, for example, 13.56 MHz, 27 MHz, 2 MHz, 400 kHz, or combinations thereof. Plasma power supply 506 and wafer bias power supply 516 may be appropriately sized to supply a range of powers in order to achieve desired process performance. For example, in one embodiment of the present invention, the plasma power supply 506 may supply the power in a range of 500 to 10000 Watts, and the wafer bias voltage power supply 516 may supply a bias voltage in a range of 10 to 2000 V. In addition, the TCP coil 510 and/or the electrode 520 may be comprised of two or more sub-coils or sub-electrodes, which may be powered by a single power supply or powered by multiple power supplies.

As shown in FIG. 5, the plasma processing system 500 further includes a gas source/gas supply mechanism 530. The gas source 530 includes a first component gas source 532, a second component gas source 534, and optionally, additional component gas sources 536. The various component gases will be discussed below. The gas sources 532, 534, and 536 are in fluid connection with process chamber 504 through a gas inlet 540. The gas inlet 540 may be located in any advantageous location in process chamber 504, and may take any form for injecting gas. Preferably, however, the gas inlet 540 may be configured to produce a “tunable” gas injection profile, which allows independent adjustment of the respective flow of the gases to multiple zones in the process chamber 504. The process gases and byproducts are removed from the chamber 504 via a pressure control valve 542, which is a pressure regulator, and a pump 544, which also serves to maintain a particular pressure within the plasma process chamber 504 and also provides a gas outlet. The gas source/gas supply mechanism 530 is controlled by the controller 524. A Kiyo system by Lam Research Corporation may be used to practice an embodiment of the invention.

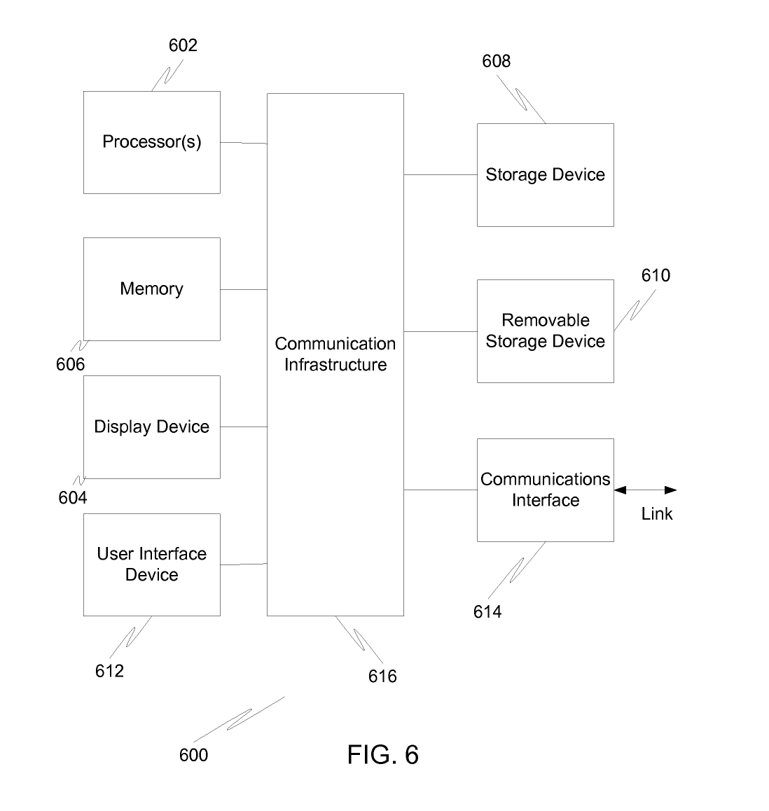

FIG. 6 is a high level block diagram showing a computer system 600, which is suitable for implementing a controller 524 used in embodiments of the present invention. The computer system may have many physical forms ranging from an integrated circuit, a printed circuit board, and a small handheld device up to a huge super computer. The computer system 600 includes one or more processors 602, and further can include an electronic display device 604 (for displaying graphics, text, and other data), a main memory 606 (e.g., random access memory (RAM)), storage device 608 (e.g., hard disk drive), removable storage device 610 (e.g., optical disk drive), user interface devices 612 (e.g., keyboards, touch screens, keypads, mice or other pointing devices, etc.), and a communication interface 614 (e.g., wireless network interface). The communication interface 614 allows software and data to be transferred between the computer system 600 and external devices via a link. The system may also include a communications infrastructure 616 (e.g., a communications bus, cross-over bar, or network) to which the aforementioned devices/modules are connected.

Information transferred via communications interface 614 may be in the form of signals such as electronic, electromagnetic, optical, or other signals capable of being received by communications interface 614, via a communication link that carries signals and may be implemented using wire or cable, fiber optics, a phone line, a cellular phone link, a radio frequency link, and/or other communication channels. With such a communications interface, it is contemplated that the one or more processors 602 might receive information from a network, or might output information to the network in the course of performing the above-described method steps. Furthermore, method embodiments of the present invention may execute solely upon the processors or may execute over a network such as the Internet in conjunction with remote processors that shares a portion of the processing.

The term “non-transient computer readable medium” is used generally to refer to media such as main memory, secondary memory, removable storage, and storage devices, such as hard disks, flash memory, disk drive memory, CD-ROM and other forms of persistent memory and shall not be construed to cover transitory subject matter, such as carrier waves or signals. Examples of computer code include machine code, such as produced by a compiler, and files containing higher level code that are executed by a computer using an interpreter. Computer readable media may also be computer code transmitted by a computer data signal embodied in a carrier wave and representing a sequence of instructions that are executable by a processor.

Features are opened in the silicon containing mask layer using the patterned organic mask (step 108), where the opened features in the silicon containing layer have a CD less than half the CD of the features in the organic mask. An opening gas is flowed into the etch chamber (step 204). In an example of a recipe, the opening gas is 100 sccm CHF₃, 300 sccm CF₄, 160 sccm N₂, and 100 sccm He. The pressure is maintained at 12 mTorr. The opening gas is formed into a plasma (step 208). 900 watts of RF is provided by the TCP coil to form the opening gas into a plasma. A pulsed bias is provided (step 212). In this example, the bias voltage is 190 volts at an RF frequency of 13.56 MHz. A duty cycle of 25% is provided at a pulse frequency 200 Hz. The process is maintained for 100 seconds. The flow of the opening gas is stopped (step 216).

FIG. 4B is a schematic cross-sectional view of the stack 400 after features 428 are opened in the silicon containing mask layer 416 using the photoresist mask 420. In this example the CD (CD1) of the photoresist features is at least 40 nm and the CD (CD2) at the bottom of the features 428 of the silicon containing mask layer 416 is no more than 18 nm, so that the CD at the bottom of the features of the silicon containing mask layer 416 is less than half the CD of the photoresist features.

Using the features with reduced CD in the silicon containing layer as a mask, features with reduced CD are etched into the organic underlayer (step 112). An etch gas is flowed into the etch chamber (step 304). The etch gas is formed into a plasma (step 308). The flow of the etch gas is stopped (step 312).

An example of a recipe for etching the organic underlayer provides a pressure of 5 mTorr. An etch gas is flowed into the chamber (step 304) comprising 20 sccm Cl₂, 50 sccm HBr, 90 sccm O₂, and 50 sccm N₂. The etch gas is formed into a plasma by providing 300 watts TCP power (step 308). A bias of 250 volts is provided. The process is maintained for 45 seconds.

FIG. 4C is a schematic cross-sectional view of the stack 400 after the features 432 with reduced CD are etched into the organic underlayer 412. In this example, the CD (CD1) of the photoresist features is at least 40 nm and the CD (CD3) of the features 432 of the organic underlayer 412 is no more than 18 nm, so that the CD (CD3) of the features of the organic underlayer 412 is less than half the CD (CD1) of the features 424 of the photoresist mask 420. In some embodiments, the photoresist mask 420 may be partially or completely removed during etching of the organic underlayer or opening the silicon containing mask layer, however, the photoresist mask 420 is shown to show CD1.

The reduced CD features in the organic underlayer 412 are used to etch reduced CD features into the etch layer 408 (step 116), where the reduced CD features have a CD less than half the CD of the features in the organic mask.

In an example of a recipe for etching the etch layer 412, which in this embodiment is silicon oxide, a pressure of 3 mTorr is provided. An etching gas comprising 90 sccm CF₄ and 45 sccm CHF₃ is flowed into the chamber. The etch gas is formed into a plasma by providing 600 watts TCP power. A bias voltage is of 160 volts is provided. The process is maintained for 42 seconds.

FIG. 4D is a schematic cross-sectional view of the stack 400 after the features 436 with reduced CD are etched into the etch layer 408. In this example, the CD (CD1) of the photoresist features is at least 40 nm and the CD (CD4) of the features 436 of the etch layer 408 is no more than 18 nm, so that the CD (CD4) of the features of the etch layer 408 is less than half the CD (CD1) of the features 424 of the photoresist mask 420. In some embodiments, the photoresist mask 420 may be partially or completely removed during etching of the organic underlayer or opening the silicon containing mask layer or etching the etch layer, however, the photoresist mask 420 is shown to show CD1.

This embodiment of the invention allows for shrinkage of both trenches and vias. Other embodiments of the invention may use other fluorocarbon opening gases with an etching component and polymerizing component. Preferably, the opening gas has a ratio of etching component to polymerizing component of between 4:1 to 1:3, by volume. In addition, various embodiments of the invention have a pulse bias with a duty cycle of between 20% to 90% at a pulse frequency between 10 Hz to 1 kHz with a bias voltage amplitude of between 100 to 400 volts with an RF frequency between 2 to 60 MHz. In other embodiments, the etch layer may be a conductive layer, which uses a silicon containing mask.

Other embodiments of the invention may use tri-layer masks, with a top layer of photoresist above a SiARC above an organic layer above a cap layer. A layer, such as a titanium nitride (TiN) layer, may be below the cap layer. A silicon oxide layer may be below the TiN layer. In such an embodiment, the SiARC layer may be used as an etch mask for the organic layer, cap layer, TiN layer, or silicon oxide layer. In other embodiments, other layers may be used as masks for layers below.

Current conventional lithography provides photoresist features with CD of around 40 nm or 60 nm. Embodiments of the invention allow such photoresist features to provide etch layer features as low as 12 nm to 18 nm. Some embodiments of the invention provide a shrink so that the shrunk CD is less than one third the original CD, which for example may shrink a 60 nm photoresist mask feature to 18 nm at the bottom of the silicon containing mask layer.

Without being bound by theory it is believed that the off part of the duty cycle of the bias pulsing causes a net polymer deposition, which causes the tapering, while the on part of the duty cycle of the bias pulsing cause a net removal of the polymer deposition or a reduced polymer deposition. The longer the percentage that the duty cycle is off, the more the taper of the etch. As a result, the duty cycle may be used as a control of the etch taper, with an increase in the off duty cycle causing an increase in the taper.

In other embodiments of the invention other hydrofluorocarbons or fluorocarbons may be used as a polymerizing component. In addition, other halogen containing components, such as hydrofluorocarbons or fluorocarbons may be used as the etchant component. Other embodiments of the invention have etch layers that are other dielectric layers, such as a layer comprising silicon oxide.

While this invention has been described in terms of several preferred embodiments, there are alterations, permutations, and various substitute equivalents, which fall within the scope of this invention. It should also be noted that there are many alternative ways of implementing the methods and apparatuses of the present invention. It is therefore intended that the following appended claims be interpreted as including all such alterations, permutations, and various substitute equivalents as fall within the true spirit and scope of the present invention.

1. A method for etching with CD reduction, an etch layer disposed below a silicon containing mask layer under a patterned organic mask with features with a first CD, comprising:
opening features in the silicon containing mask layer using the patterned organic mask, comprising:
providing an opening gas with an etchant component and polymerizing component;
forming the opening gas into a plasma; and
providing a pulsed bias with a pulse frequency between 10 Hz and 1 kHz, which etches features through the silicon containing mask layer with a second CD which is less than one third of the first CD, forming a pattern in the silicon containing mask layer; and
transferring the pattern of the silicon containing mask layer to the etch layer.

2. The method, as recited in claim 1, wherein the bias voltage is provided by a bias RF with a frequency between 2 and 60 MHz.

3. The method, as recited in claim 2, wherein the silicon containing mask layer is a silicon containing antireflective coating.

4. The method, as recited in claim 3, wherein the transferring the pattern of the silicon containing mask layer to the etch layer, comprises:
transferring the pattern of the silicon containing mask layer to an organic underlayer; and
transferring a pattern from the organic underlayer to the etch layer.

5. The method, as recited in claim 4, wherein a duty cycle of the pulsed bias is between 20% to 90%.

6. The method, as recited in claim 5, wherein an off part of the duty cycle causes a net polymer deposition.

7. The method, as recited in claim 6, wherein an on part of the duty cycle causes a net removal of the polymer deposition or a reduced polymer deposition.

8. The method, as recited in claim 7, wherein the duty cycle is used to control tapering.

9. The method, as recited in claim 8, wherein the polymerizing component is a hydrofluorocarbon or fluorocarbon.

10. The method, as recited in claim 9, wherein the etchant component is a halogen containing component.

11. The method, as recited in claim 1, wherein the silicon containing mask layer is a silicon containing antireflective coating.

12. The method, as recited in claim 1, wherein the transferring the pattern of the silicon containing mask layer to the etch layer, comprises:
transferring the pattern of the silicon containing mask layer to an organic underlayer; and
transferring a pattern from the organic underlayer to the etch layer.

13. The method, as recited in claim 1, wherein a duty cycle of the pulsed bias is between 20% to 90%.

14. The method, as recited in claim 13, wherein an off part of the duty cycle causes a net polymer deposition or a reduced polymer deposition.

15. The method, as recited in claim 14, wherein an on part of the duty cycle causes a net removal of the polymer deposition.

16. The method, as recited in claim 15, wherein the duty cycle is used to control tapering.

17. The method, as recited in claim 1, wherein the polymerizing component is a hydrofluorocarbon or fluorocarbon.

18. The method, as recited in claim 17, wherein the etchant component is a halogen containing component.

19. A method for etching with CD reduction, an etch layer disposed below an organic underlayer disposed below a silicon containing mask layer under a patterned organic mask with features with a first CD, comprising:
opening features in the silicon containing mask layer using the patterned organic mask, comprising:
providing an opening gas with an etchant component and polymerizing component;
forming the opening gas into a plasma; and
providing a pulsed bias with a pulse frequency between 10 Hz and 1 kHz, which etches features through the silicon containing mask layer with a second CD of no more than 18 nm, which is less than half the first CD of at least 40 nm, forming a pattern in the silicon containing mask layer;
transferring the pattern of the silicon containing mask layer to the organic underlayer; and
transferring the pattern of the organic underlayer to the etch layer.

20. The method, as recited in claim 1, wherein the first CD is at least 60 nm and wherein the second CD is of no more than 18 nm.
